(19) United States
(12) Patent Application Publication
(10) Pub. No.: US 2015/0338450 A1
(43) Pub. Date: Nov. 26, 2015

(54) METHOD FOR ANALYZING A CABLE BY COMPENSATING THE DISPERSION EFFECT OF A SIGNAL WHEN IT IS PROPAGATED WITHIN SAID CABLE

(71) Applicant: COMMISSARIAT A L'ENERGIE ATOMIQUE ET AUX ENERGIES ALTERNATIVES, Paris (FR)

(72) Inventors: Lola EL SAHMARANY, Cachan (FR); Laurent SOMMERVOGEL, Jouy-en-Josas (FR); Fabrice AUZANNEAU, Massy (FR); Nicolas GREGIS, Antony (FR); Luca INCARBONE, Paris (FR)

(21) Appl. No.: 14/759,163

(22) PCT Filed: Dec. 30, 2013
(86) PCT No.: PCT/EP2013/078099

§ 371 Date: Jul. 2, 2015

(30) Foreign Application Priority Data
Jan. 4, 2013 (FR) 13 50048

(51) Int. Cl. G01R 31/02; G01R 17/00; G01R 31/11

(52) U.S. Cl. CPC G01R 31/021; G01R 31/11; G01R 17/00

(57) ABSTRACT

A method for analyzing a cable, into which a first reference signal g is injected, calculates the dynamic correlation between a measurement f of the reflection, from at least one discontinuity in the cable, of the injected signal g and a second reference signal gₚ equal to the first reference signal g weighted by a frequency-dependent function modeling the propagation of a wave along the cable.

The invention relates to a method for analyzing electrical cables and in particular long electrical cables. It especially applies to the fields of electronics, signal processing and reflectometry.

Cables for supplying power or transmitting information are present in all electrical systems. These cables are subjected to the same constraints as the systems which they connect and may become exposed to failures. It is therefore necessary to be able to analyze their state and provide notification of the detection of defects, but also their location and type, in order to help with maintenance.

Conventional reflectometry methods allow this type of test to be performed. These methods use test signals, referred to as probe signals or reflectometry signals in the rest of this description. The shape of these signals changes significantly during their round trip in a cable, these changes being the result of physical attenuation and dispersion effects.

Reflectometry methods use a principle similar to the radar: an electrical signal, the probe signal, which is often a high-frequency or wideband signal, is injected at one or more points along the cable to be tested. Said signal propagates in the cable or the network and a part of its energy is reflected when it meets an electrical discontinuity. An electrical discontinuity may result from a splice, end of cable or defect. Analysis of the reflected signals at point of injection provides information regarding the presence and location of these discontinuities, and therefore of potential defects. The analysis is conventionally conducted in time- or frequency domain. These methods are designated by the acronyms TDR (time domain reflectometry) and FDR (frequency domain reflectometry), respectively.

One problem resides in the fact that in a dispersive medium, such as electrical cable, the propagation speed of electromagnetic wave varies with frequency. Thus, the frequency components of any signal (e.g. pulse), injected into a cable, propagate at different speed. The injected signal is therefore deformed as it propagates. Similarly, the reflected signal is deformed and its deformation becomes greater as the distance travelled by the wave increases. Attenuation and deformation of the reflected signal greatly degrades the quality of the measurement carried out with a view to detecting and locating any defects impacting the cable's performance.

More precisely, this deformation has two negative effects on the analysis. Firstly, deformation of the reflected signal affects the localization of defects in the cable. In case of pulsed signal, the deformation has the effect of transforming the signal into a flattened dome. However, the localization of a discontinuity or defect involves measuring the difference between the abscissa of the injection point and the abscissa of the echo. If the reflected signal is greatly deformed, there is a large uncertainty in the measurement of the abscissa of the echo. The error thus obtained in the localization is not constant and varies as function of the distance.

Furthermore, deformation of the reflected signal also affects defect detection. Specifically, the energy of the received signal is lower than that of the injected signal, because of the attenuation. In addition, the dispersion leads to temporal dilatation of the signal and consequently the amplitude of the echoes decreases. However, the closer the amplitude of the echoes is to the amplitude of measurement noise, the more difficult it will be the detection of a discontinuity.

There are various known solutions that mitigate the drawbacks created by dispersion in electrical cables, and especially long cables.

A first solution consists of utilizing an active cable that allows the regeneration of injected signal as it propagates along the cable. Thus, at regular intervals along the cable it is possible to increase the amplitude of the signal in order to compensate its attenuation. This solution is considered as an intrusive method that requires existing infrastructure to be modified, and it is not suitable for every cable type.

Another solution consists of choosing a particular waveform for the injected signal so that the negative effect of dispersion is minimized. The thesis document “Time domain transmission line measurements with the speedy delivery pulse, Joseph Zachary Zugelter, thesis, The University of Texas at Austin, December 2010”, proposes to choose a particular shape for the signal to inject, this shape being invariant in a dispersive medium. In the same field, the French patent application of the Applicant published under number FR 2 946 149 proposes to inject a “ramp” type signal. The abscissae of the points used to calculate the delay between the injected signal and the reflected signal here correspond, on the one hand, to the foot of the injected ramp and, on the other hand, to the intersection with the axis of the abscissae of the virtual line that passes through the points at 20% and 80% of the maximum amplitude of the dispersed reflected signal. However, these methods are limited to particular waveform of a signal.

In addition, the thesis document “reflectometric analysis of transmission line networks, Carine Neus, Brussels March 2011”, proposed a solution that allows direct compensation of the reflected signal based on the knowledge of the propagation constant and the length of the cable. The proposed solution consists of transposing the reflected signal received into the frequency domain and multiplying it by the inverse of a term characteristic of the wave propagation along the cable. The drawback of this solution is that the length of the cable should be known with precision, this information not always being available and also sometimes being the objective of the reflectometry analysis.

The invention makes it possible to overcome the aforementioned limitations of prior-art solutions by providing a method for compensating for the distortion, or more generally deformation, of a signal back propagated along an electrical cable to be analyzed.

The invention is applicable to any type of reflectometry signal and requires no intrusion into the cable under test, and there is no need to know the length L of the cable to be tested.

There is no need to modify the injected or reflected signal. The invention involves a modification of the reference signal, this modification being associated with a correlation between the modified reference signal and the reflected signal.

Thus, one subject of the invention is a method for analyzing a cable into which a first reference signal g is injected, characterized in that it consists in calculating the dynamic correlation between a measurement f of the reflection, from at least one discontinuity in said cable, of said injected signal g and a second reference signal gₚ equal to the first reference signal g weighted by a frequency-dependent function modeling the propagation of a wave along said cable.

According to one particular aspect of the invention, the weighted second reference signal gₚ is determined by executing at least the following steps:
Constructing, in the frequency domain, the spectrum G_{P} of said weighted second reference signal gₚ by calculating the product of the spectrum Gₒ of said first reference signal g and a frequency-dependent first weighting coefficient that is characteristic of the propagation of a wave along said cable; and
Applying an inverse frequency transform to said spectrum G_{P} of said weighted second reference signal in order to obtain the weighted reference signal gₚ.

According to one particular aspect of the invention, the frequency-dependent first weighting coefficient that is characteristic of the propagation of a wave along said cable is estimated by the term exp(−γpTₑv_{φ}), where γ is the propagation constant of said cable, V_{φ} is the phase velocity of said cable, Tₑ is the sampling period of said measurement f of the reflected signal and p is a positive integer.

According to one particular aspect of the invention, the propagation constant γ is estimated on the basis of knowledge of the following parameters: the resistance per unit length R, inductance per unit length L, conductance per unit length G and capacitance per unit length C of said cable.

According to one particular aspect of the invention, the spectrum G_{P} of said weighted second reference signal gₚ is furthermore weighted by a second weighting coefficient so as to re-center the result of the dynamic correlation toward the origin.

According to one particular aspect of the invention, said second weighting coefficient is equal to

$$exp ( \frac{2 iπ kp}{N} ) ,$$

where p and k are two positive integers and N is the number of signal samples used to calculate the dynamic correlation.

According to one particular aspect of the invention, the dynamic correlation is calculated using the following relationship R′_{fg}(p)=Σₙ₌₀^{N-p-1}f(n)gₚ(n+p), where N is the number of signal samples considered.

According to one particular aspect of the invention, the samples of said weighted reference signal gₚ are assumed to be constant over a preset length of time.

In one variant embodiment, the method according to the invention furthermore comprises a step of finding at least one extremum of said dynamic correlation.

In one variant embodiment, the method according to the invention furthermore comprises a step of determining the distance between the origin and said extremum.

Other subjects of the invention are a device for analyzing a cable comprising means suitable for implementing the analysis method according to the invention; a reflectometry system comprises a device for analyzing a cable; a computer program containing instructions for executing the method for analyzing a cable according to the invention, when the program is executed by a processor; and a storage medium that is readable by a processor, on which a program comprising instructions for executing the method for analyzing a cable according to the invention, when the program is executed by a processor, is stored.

Other features and advantages of the present invention will become more clearly apparent on reading the following description with regard to the appended drawings, which show:

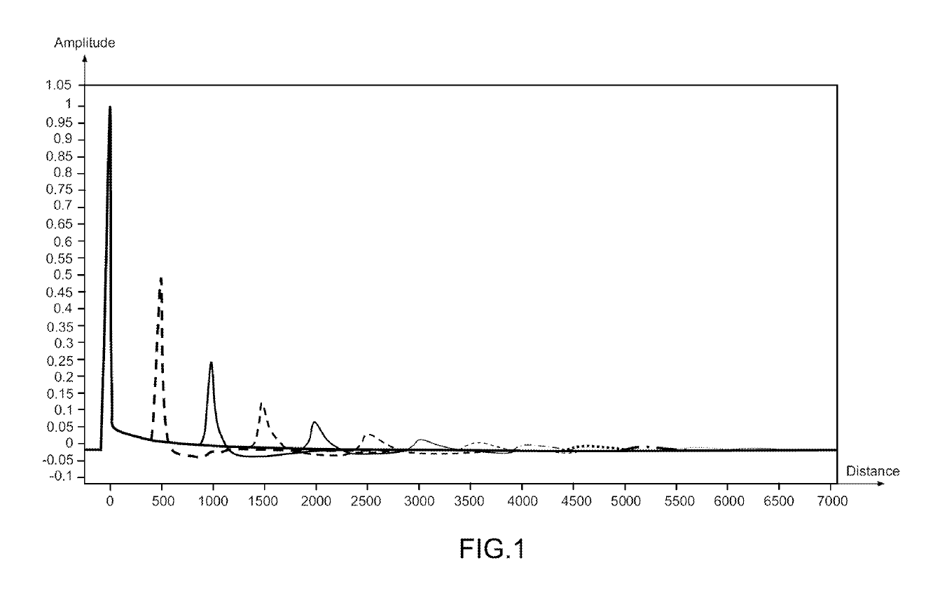

FIG. 1, is a temporal diagram that illustrates the impact of dispersion and attenuation phenomena during propagation of a signal along an electrical cable;

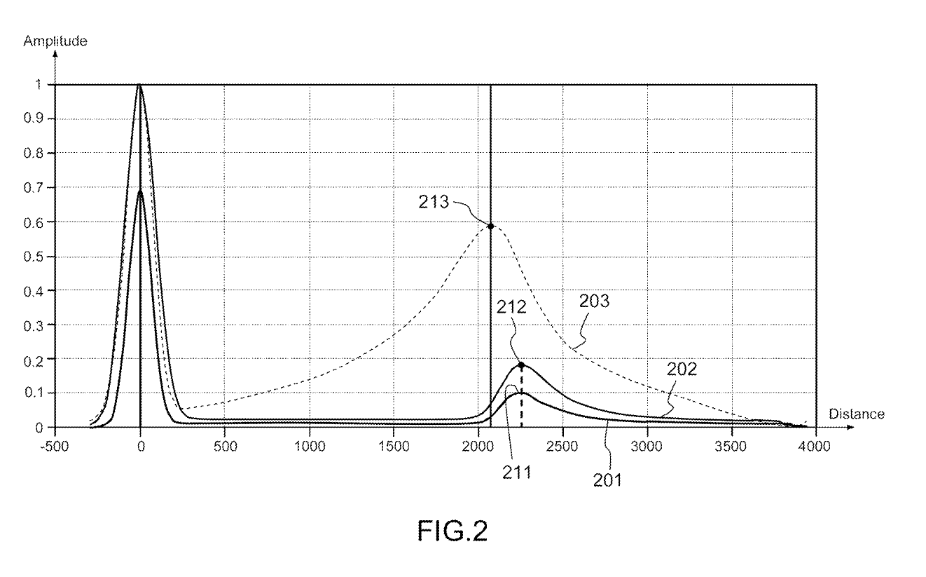

FIG. 2, illustrates the results obtained by implementing the method according to the invention and the improvement in the precision of a defect localization as compared to prior-art techniques; and

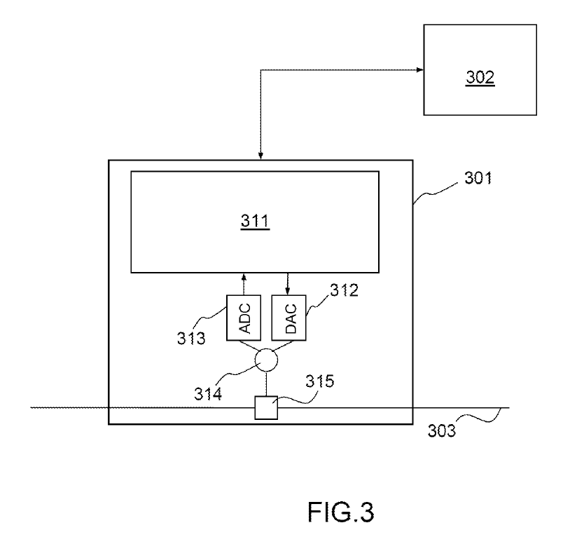

FIG. 3, represents a scheme of a reflectometry system that comprises means for implementing the invention.

Correlation operations are widely used in reflectometry to improve the signal-to-noise ratio of the reflected signal and subsequently to improve the precision of the localization of an electrical defect. The correlation allows the measurement of statistical resemblance of a signal to a reference signal (inter-correlation) or indeed to itself (auto-correlation). Therefore, it is suitable to be used for post-processing of signals assumed to be irregular, as is the case for a reflectogram.

The discrete correlation R_{fg} between two real and causal signals f and g is written using the following relationship:

$${R}_{fg} ( n ) = {\sum }_{p = 0}^{N - 1} f ( p ) g ( n + p )$$

The signals being considered are assumed to be periodic and continuous. Circular correlation is spoken of in this case. This implies that overflow of the index n+p is calculated modulo N. When the signal being considered is not periodic (case of a pulse for example), the following linear correlation definition is used instead:

$${R}_{fg} ( n ) = {\sum }_{p = 0}^{N - n - 1} f ( p ) g ( n + p )$$

The aforementioned relationships are given in the discrete domain, i.e. the signals f and g are sampled at a frequency Fₑ=1/(N·Tₑ). In other words the signal is sampled at the temporal instants t=nTₑ, where n is a positive integer.

In the context of a temporal reflectometry system, the signal g is the reference signal injected into the cable for analysis, and the signal f is the signal reflected along the cable and measured at an acquisition point (e.g. the injection point).

FIG. 1 illustrates, on an amplitude-distance graph, the result of the linear correlation operation R_{fg} for a reference signal pulse propagating along a cable of 7000 m in which various cuts have been produced every 500 m. It should be noted that the deformation of the result of the linear correlation increases with the distance of the electrical defect from the injection point, making it a very difficult to localize the defect existed at a distance of more than 3000 m from the injection point.

In order to improve the precision of reflectometry measurements allowing a defect to be detected and located, the invention consists in using, instead of the conventional correlation operation, a dynamic correlation operation in which the signal g used as the reference is modified so as to take into account the deformation, in the absence of defects, that the injected signal undergoes during its propagation along the cable being tested.

The formula of the linear correlation operation is replaced by the following adaptive correlation formula:

$${R}_{fg}^{′} ( p ) = {\sum }_{n = 0}^{N - p - 1} f ( n ) {g}_{p} ( n + p )$$

The coefficients of the modified reference signal gₚ are calculated from a model of the propagation along the cable being tested. This model may be derived from the well-known telegrapher's equations. The aim of this model is to reflect the attenuation of the signal as it propagates along a perfect (i.e. defect-free) cable.

Firstly, the spectrum or Fourier transform Gₚ of the discrete signal gₚ is determined by calculating the product of the Fourier transform Gₒ of the signal injected into the cable under test and an attenuation function or coefficient modeling the propagation along the cable under test, this coefficient or function being frequency dependent.

Secondly, the spectrum obtained is re-centered in order to compensate for the frequency shift induced by the weighting of the attenuation coefficient.

For example, the following relationship allows a reference signal weighted by an attenuation coefficient modeling the propagation along the cable under test to be obtained.

$${G}_{p} ( k ) = {G}_{0} ( k ) exp ( - γ ( k ) {pT}_{e} {v}_{ϕ} ( k ) exp ( \frac{2 iπ kp}{N} ) \qquad ( 1 )$$

Expression (1) allows three terms to be defined. The first term G₀(k) is the Fourier transform of the signal injected into the cable under test.

The second term exp(−γpTₑv_{φ}) allows the effect of the propagation of the wave along the cable in terms of attenuation and dispersion to be modeled. γ is the propagation constant, also referred to as the propagation constant per unit length. It is a question of a complex number γ=α+jβ, where α is the attenuation coefficient per unit length and β is the phase constant per unit length. The propagation constant γ depends on the frequency of the signal and on the properties of the cable. It may be estimated from a propagation model and for example on the basis of knowledge of the following parameters: the resistance per unit length R, inductance per unit length L, conductance per unit length G and capacitance per unit length C of the cable. Such a propagation model is for example described in the work “Physique Appliquée, G. Pinson, chapter Ligne de transmission”. V_{φ}, is the phase speed, which also depends on the frequency of the signal. Tₑ is the sampling period of the signal.

The third term

$$exp ( \frac{2 iπ kp}{N} )$$

allows the delay related to the introduction of the second term to be compensated for in order to re-center the result of the dynamic correlation toward the origin.

The method according to the invention therefore consists, firstly, in determining the coefficients Gₚ(k) of the respective Fourier transforms of the reference signal adapted for the propagation constant γ, the phase speed V_{φ} and the sampling period Tₑ, and the Fourier transform of the injected signal G₀.

Secondly, an inverse Fourier transform is applied to the coefficients Gₚ(k) in order to obtain temporal samples of the adapted reference signal gₚ(n). These samples may be calculated in advance and stored in a memory if it is desired to decrease the complexity and runtime of the calculations or, in contrast, be calculated on the fly in parallel with the calculation of the dynamic correlation to decrease the required memory space.

From the modified reference signal gₚ, the dynamic correlation R′_{fg}(p)=Σₙ₌₀^{N-p-1}f(n)gₚ(n+p) is calculated and subsequently one or more defects in the cable under test is located.

In one variant embodiment of the invention, it is possible to decrease the number of coefficients of the modified reference signal gₚ to be calculated and/or stored by assuming that, over a given time horizon, the attenuation of the signal is constant.

FIG. 2 illustrates, by way of an amplitude/distance graph, comparative results obtained without correlation, with a linear correlation and with a dynamic correlation adapted according to the invention for an electrical defect located at a distance of 2000 m from the injection point, respectively.

In the example in FIG. 2, the injected signal is a pulse. The graph in FIG. 2 is a temporal reflectogram that shows three measurements carried out using three different methods to locate an electrical defect in a cable under test. The first curve 201 is simply a measurement of the pulsed signal reflected from the defect located at 2000 m from the injection point. The second curve 202 is the result of a standard linear correlation of the reflected signal with the injected reference signal. Lastly, the third curve 203 represents the result obtained by applying the dynamic correlation using an adapted reference signal. The location of the defect is determined by finding the abscissa of the local maximum 211, 212, 213 of the curve. It should be noted that for the first two curves 201, 202 an error of about 13% is obtained relative to the precise position 211, 212 of the defect to be located. The use of the method according to the invention, illustrated by the third curve 203, allows the precision of the location measurement to be improved by decreasing the relative error to 3.7%. Furthermore, the amplitude of the correlation peak 213 is increased as compared to the first two curves, thereby also improving detection of the defect.

FIG. 3 schematically shows, in a diagram, an example reflectometry system 301 able to implement the method according to the invention.

A reflectometry system 301, or reflectometer, comprises at least one electronic component 311 of the integrated circuit type, such as a programmable logic circuit, for example an FPGA or microcontroller; a digital to analog converter 312 for injecting a test signal into the cable to be tested 303; an analog to digital converter 313 for receiving the signal reflected from impedance mismatches or discontinuities in the cable; a coupling device 314 between the analog to digital converter 313 and the digital to analog converter 312; and a coupling means 315 between an input/output of the device 301 and the cable to be tested 303. The coupling means is suitable for injecting the signal output from the digital to analog converter 312 into the cable 303 and for receiving the one or more reflected signals.

The system 301 may be implemented using an electronic board on which various constituent elements 312, 313, 314 are placed. The coupling and injecting means 315 is connected to an input/output of the board.

Furthermore, a processing unit 302, such as a computer, digital personal assistant, etc. may be used to control the reflectometry device 301 and to display the results of the measurements on a human/machine interface.

The electronic component 311 is suitable for implementing, on the one hand, the processing steps required to generate the injection signal and, on the other hand, the steps required to implement the method according to the invention allowing a reflectogram to be obtained that is transmitted to the processing unit 302.

In one variant of the invention, the injection signal may be generated by a different component from the one that executes the method according to the invention for analysis of the reflected signal.

The method according to the invention may be implemented using hardware and/or software elements. It may also be implemented using a computer program containing instructions for its execution. The computer program may be stored on a storage medium that is readable by a processor.

1. A method for analyzing a cable into which a first reference signal g is injected, comprises calculating the dynamic correlation between a measurement f of the reflection, from at least one discontinuity in said cable, of said injected signal g and a second reference signal gₚ equal to the first reference signal g weighted by a frequency-dependent function modeling the propagation of a wave along said cable in the absence of defects.

2. The method for analyzing a cable as claimed in claim 1, in which the weighted second reference signal gₚ is determined by executing at least the following steps:
constructing, in the frequency domain, the spectrum G_{P} of said weighted second reference signal gₚ by calculating the product of the spectrum G₀ of said first reference signal g and a frequency-dependent first weighting coefficient that is characteristic of the propagation of a wave along said cable; and
applying an inverse frequency transform to said spectrum G_{P} of said weighted second reference signal in order to obtain the weighted reference signal gₚ.

3. The method for analyzing a cable as claimed in claim 2, in which the frequency-dependent first weighting coefficient that is characteristic of the propagation of a wave along said cable is estimated by the term exp(−γpTₑv_{φ}), where γ is the propagation constant of said cable, V_{φ} is the phase velocity of said cable, Tₑ is the sampling period of said measurement f of the reflected signal and p is a positive integer.

4. The method for analyzing a cable as claimed in claim 3, in which the propagation constant γ is estimated on the basis of knowledge of the following parameters: the resistance per unit length R, inductance per unit length L, conductance per unit length G and capacitance per unit length C of said cable.

5. The method for analyzing a cable as claimed in claim 2, in which the spectrum Gₚ of said weighted second reference signal gₚ is furthermore weighted by a second weighting coefficient so as to re-center the result of the dynamic correlation toward the origin.

6. The method for analyzing a cable as claimed in claim 5, in which said second weighting coefficient is equal to
$$exp ( \frac{2 i π kp}{N} ) ,$$
where p and k are two positive integers and N is the number of signal samples used to calculate the dynamic correlation.

7. The method for analyzing a cable as claimed in claim 1, in which the dynamic correlation is calculated using the following relationship R′_{fg}(p)=Σₙ₌₀^{N-p-1}f(n)gₚ(n+p), where N is the number of signal samples considered, n being a positive integer.

8. The method for analyzing a cable as claimed in claim 1, in which the samples of said weighted reference signal gₚ are assumed to be constant over a preset length of time.

9. The method for analyzing a cable as claimed in claim 1, in which said method furthermore comprises a step of finding at least one extremum of said dynamic correlation.

10. The method for analyzing a cable as claimed in claim 9, in which said method further comprises a step of determining the distance between the origin and said extremum.

11. A device for analyzing a cable comprising means suitable for implementing the analysis method as claimed in claim 1.

12. A reflectometry system comprising a device for analyzing a cable as claimed in claim 11.

13. A computer program containing instructions for executing the method for analyzing a cable as claimed in claim 1, when the program is executed by a processor.

14. A storage medium that is readable by a processor, on which a program comprising instructions for executing the method for analyzing a cable as claimed in claim 1, when the program is executed by a processor, is stored.
